(19) United States
(12) Patent Application Publication
(10) Pub. No.: US 2002/0000657 A1
(43) Pub. Date: Jan. 3, 2002

(54) PLATED CHROME SOLDER DAM FOR HIGH POWER MMICS

(76) Inventors: CHENG P. WEN, MISSION VIEJO, CA (US); RAWLEY D. LARSON, LONG BEACH, CA (US)

Correspondence Address: PATENT DOCKET ADMINISTRATION, RAYTHEON COMPANY, P O BOX 902, 2000 E EL SEGUNDO AVENUE, EL SEGUNDO, CA, 902450902

(21) Appl. No.: 09/306,075

(22) Filed: May 6, 1999

(51) Int. Cl. H01L 23/48; H01L 23/52; H01L 29/40

(52) U.S. Cl. 257/737

(57) ABSTRACT

A microwave device includes a circuit element and a chromium layer disposed over the circuit element. The circuit element may have an electrolytically plated gold surface. The microwave device further includes a bump disposed over the circuit element. The bump may include silver, while the chromium layer may include a portion extending from the bump to form a solder dam. A native oxide forms on the portion of the chromium layer to inhibit solder contamination and/or silver migration. The native oxide may also act as an adhesion agent for a subsequently deposited dielectric passivation layer.

### BACKGROUND OF THE INVENTION

1. Field of the Invention

The invention relates generally to monolithic, microwave integrated circuits (MMICs) and, more particularly, to the fabrication of flip-chip bumps therefor.

2. Description of the Related Art

Flip-chip monolithic, microwave integrated circuits (MMICs) have been recognized as a low cost approach to fabricating microwave transmit/receive modules for active array radar. Flip-chip fabrication involves mounting the monolithic circuits face-down on a dielectric assembly substrate using a solder reflow process. MMIC devices mounted in such a fashion have exhibited superior thermal properties relative to conventional, face-up MMICs fabricated on 4-mil thick gallium arsenide substrates.

These superior thermal properties (e.g., reduced thermal resistance) have been made possible, in part, by electrolytically plated (i.e., “electroplated” or “plated”) metal (e.g., silver) thermal bumps that promote heat dissipation. The thermal bumps typically couple the dielectric substrate to circuit elements that generate significant amounts of heat, such as a plated gold bridge connecting the source electrodes of a multi-cell field effect transistor (FET). The lower device temperatures arising from such connections lead to improved electrical performance and circuit reliability. Flip-chip MMICs have also benefitted from the utilization of silver bumps for transmitting output signals off-chip to an output circuit disposed on the assembly substrate. In addition to promoting heat dissipation, these electrical bumps provide an efficient mechanism for establishing input/output connections to the MMIC.

The utilization of thermal and electrical bumps and the corresponding solder reflow approach to chip attachment has, however, raised other potential problems. For example, molten solder crawling up the side wall of a thermal bump may reach the gold bridges during the solder reflow process. To prevent solder contamination, it is necessary to have a solder dam (conventionally, a dielectric) surrounding each thermal bump to prevent the molten solder from spreading on the plated gold surface of the source electrode bridge. This potential problem is particularly acute in the absence of dielectric passivation. In addition to solder contamination, flip-chip MMICs having silver bumps may experience silver migration over the gold surface, which leads to another serious reliability concern.

In general, passivation layers have provided a layer of protection for gold bridges and other exposed metal layers of the MMIC. Unprotected circuit elements not only risk damage during the solder reflow process, but also during other subsequent processing steps, including back-side processing, on-wafer testing, wafer dicing, pick-and-place, die attachment, off-chip electrical interconnect, final clean, and packaging. Typical passivation layers have constituted a dielectric coating, such as silicon dioxide, silicon oxy-nitride, or a combination thereof.

While such dielectric layers are capable of protecting circuit elements from the environment (e.g., chemicals and dirt) and mechanical scratching, silicon dioxide and other dielectrics do not exhibit suitable bonding strengths when deposited directly on a gold surface. Thus, when current MMICs are subjected to thermal cycling or thermal shock, device failures may result from delamination at the gold/dielectric interface.

Gold-based metallization has been widely used in MMICs, gold being suitable for several elements, including bridges, crossovers, transmission line segments, and electrodes. Thick gold layers (ie., several microns) have been utilized in such instances to form low resistance, thermal paths that boost power handling capabilities and increase the Q-factor of the device. Gold-based MMICs have also been highly resistant to corrosion.

Titanium has been a conventional agent for adhering dielectric passivation layers to metal layers. A strong oxygen covalent bond between the oxidized titanium surface and the dielectric material provides the adhesive property. Techniques for depositing a thin layer (e.g., 500 Angstroms) of titanium, however, have been found to be incompatible with the electrolytic plating process. Moreover, additional masking steps are often required for using titanium with plated gold surfaces, inasmuch as titantium plating technology has been undesirable. These additional masking steps result in higher circuit fabrication costs and lower manufacturing yields.

Electrolytically plated nickel has also been found to improve adhesion at the dielectric/gold interface. While a thin layer of nickel (200 Angstroms) can be plated on top of the plated gold electrodes without the need for additional photolithography, nickel has introduced other processing complications. First, adhesion between nickel and the bump plating membrane (typically a titanium/gold interface layer) is less than desirable. As a result, the plated nickel film must be removed at selected areas to facilitate the silver bump formation. Further, nickel has been found to be inadequate as a solder dam, inasmuch as molten solder reacts readily with nickel.

For these reasons, in the non-passivation regions (e.g., at certain flip-chip and thermal bumps), the nickel layer fails to provide a solder dam for preventing molten solder from spreading over the MMIC. Past attempts to use nickel despite these drawbacks have been inadequate. These attempts, for example, have relied upon thicker dielectric layers and certain geometric design configurations to prevent the solder from reaching the nickel. Both of these approaches place undesirable design rules on the MMIC. Moreover, the extra thickness of the dielectric layer degrades the RF characteristics of the MMIC at very high frequencies (e.g., millimeter wavelengths).

### SUMMARY OF THE INVENTION

In accordance with one aspect of the present invention, a microwave device comprises a circuit element, a layer comprising chromium disposed over the circuit element, and a bump disposed over the circuit element.

In a preferred embodiment, the layer comprising chromium may comprise a ring extending from the bump. A bump plating membrane may couple the bump to the circuit element. Alternatively, the layer comprising chromium may have a portion over which the bump is disposed and the ring may comprise a solder dam. The ring, in turn, may have a surface comprising chromium oxide, and a dielectric passivation layer may be disposed on the surface. The circuit element may have a gold plated surface, and the bump may comprise either a flip-chip bump or a thermal flip-chip bump.

In accordance with another aspect of the present invention, a method is useful for forming a flip-chip bump on a circuit element of a microwave device. The inventive method comprises the steps of depositing a layer comprising chromium over the circuit element, providing a bump photoresist profile, and depositing a metal layer over the circuit element to form the flip-chip bump according to the bump photoresist profile.

According to a preferred embodiment, the method may further include the step of removing a plating membrane and a photoresist layer prior to providing the bump photoresist profile. The plating membrane and the photoresist layer may be utilized to form the circuit element. The method may still further include the step of removing a portion of the layer comprising chromium to leave a ring-shaped portion extending from the flip-chip bump. Alternatively, the step of providing a bump photoresist profile may include depositing a bump plating membrane on the layer comprising chromium. The circuit element may have a surface comprising gold. The bump photoresist profile may cover a portion of the layer comprising chromium, while the method may still further comprise the steps of removing the bump photoresist profile and allowing a native oxide to grow on the portion of the layer comprising chromium to form a solder dam. The portion of the layer comprising chromium may comprise a ring extending from the flip-chip bump. The method may still further comprise the step of depositing a dielectric material on the portion of the layer comprising chromium to form a passivation layer.

### BRIEF DESCRIPTION OF THE DRAWINGS

FIG. 1A is a plan, schematic view of a microwave device fabricated in accordance with one embodiment of the present invention;

FIG. 1B is a cross-sectional, schematic view of the microwave device of FIG. 1 A taken along the lines 1B-1B; and

FIGS. 2A-2E are cross-sectional, schematic views of a semiconductor structure at various stages of a fabrication method in accordance with the present invention.

### DETAILED DESCRIPTION OF THE INVENTION

In general, the present invention is directed to flip-chip MMICs having electrodes with electrolytically-plated gold surfaces, and a method of making same. More particularly, flip-chip MMICs may have thermal and electrical bumps disposed over electroplated gold bridges and electrodes, respectively. In accordance with the present invention, a thin chrome film or layer accommodates these electrical and thermal bumps by serving as both a solder dam during the flip-chip attachment process and a dielectric adhesion agent in the event that the circuit is passivated. The native oxide that grows on the chrome film tends not to be wetted by conventional solder, thereby forming a solder dam during solder reflow (i.e., flip-chip attachment). When silver is utilized for the electrical and thermal bumps, the chrome solder dam also inhibits silver migration over the gold surfaces.

Unlike the dielectric solder dams utilized in prior MMIC devices, the chrome solder dam may be an integral part of a chrome film over which the bump is disposed. Therefore, no additional masking steps are required. Because the work function of chrome is similar to that of titanium (the material used for bump plating membranes), the resistivity of electrical bumps is not significantly increased. There also may be no need to remove the chrome film for electrical bumps because of the excellent adhesion characteristics between evaporated titanium and the chrome surface. Therefore, in one embodiment of the present invention, a continuous chrome film is left under and surrounding each plated metal bump, thereby providing a more effective solder dam and improving the reliability of high power, flip-chip MMICs without any degradations in RF performance.

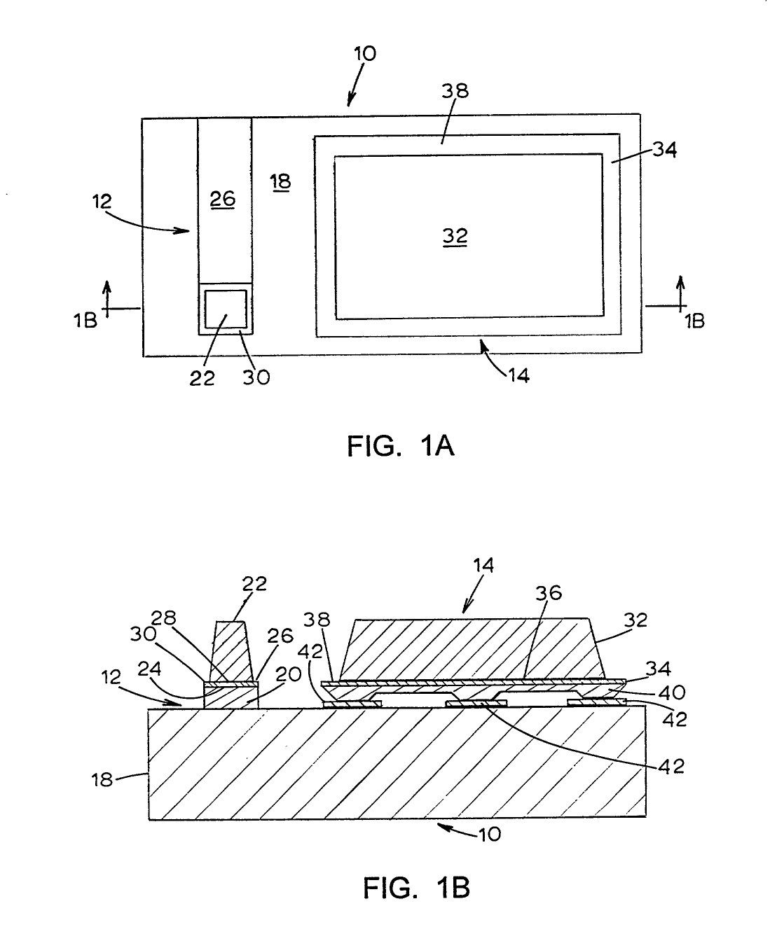

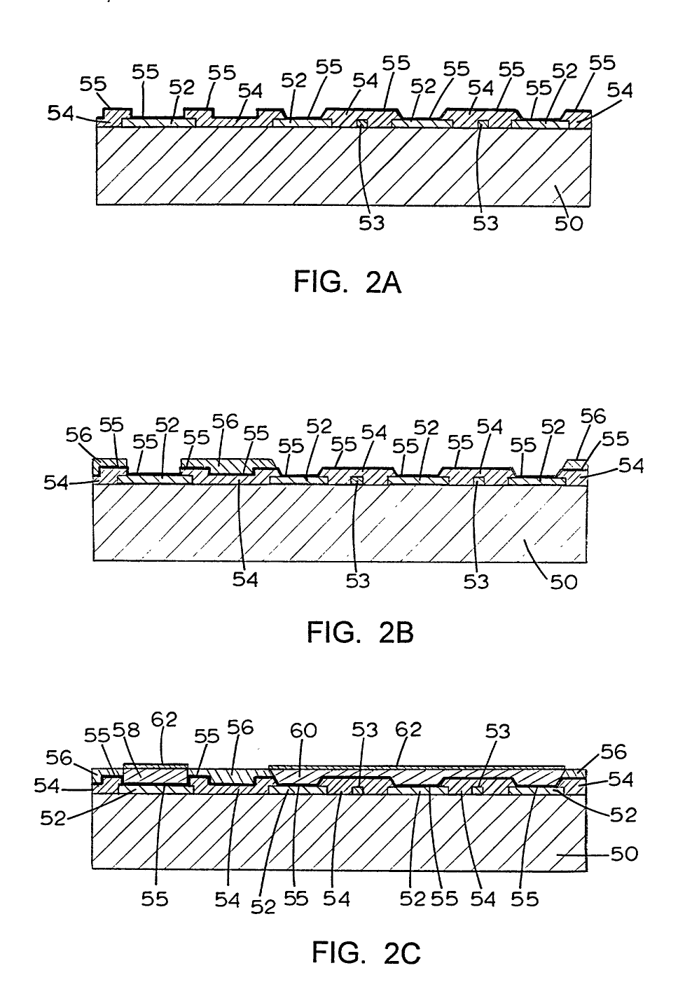

With reference now to the drawings, FIGS. 1A and 1B show schematic views of a flip-chip monolithic microwave integrated circuit (MMIC) 10 simplified for purposes of illustration. Upon flip-chip attachment to an assembly substrate (not shown), the MMIC 10 may become part of a microwave device incorporating the present invention. The simplified, flip-chip MMIC 10 has two circuit elements, which may, for example, correspond with an output conductor or transmission line 12 and a collective source electrode 14 of a multicell transistor. Both circuit elements have been fabricated on a semiconductor substrate 18, which may, for example, comprise gallium arsenide. The output conductor 12 includes a metal layer 20 (FIG. 1B) to provide a low resistance path from another MMIC element (not shown) disposed on (and/or in) the substrate 18 to a flip-chip electrical bump 22, which may provide an input/output connection to the input/output circuit on the assembly substrate to which the flip-chip MMIC 10 is soldered.

The metal layer 20 may include a plurality of low resistivity metals or metal layers, either alone or in combination, that are known to those skilled in the art to be suitable for MMICs. For example, the metal layer 20 may include layers of titanium (for improving adhesion to a gallium arsenide substrate) and gold (for, inter alia, low resistivity). The metal layer 20 may also include platinum to prevent interdiffusion of gold into the titanium layer.

According to one embodiment of the present invention, the metal layer 20 comprises an electroplated gold surface 24 (FIG. 1B) over (or alternatively upon) which an electroplated chrome (i.e., chromium) layer 26 is disposed. Alternatively, the entire metal layer 20, as well as its surface, may comprise electroplated gold. The flip-chip bump 22, in turn, is disposed over a portion 28 (FIG. 1B) of the electroplated chrome layer 26, leaving a ring-shaped portion 30 of the electroplated chrome layer 26 extending therefrom.

According to an alternative embodiment of the present invention, most (if not all) of those portions of the chrome layer 26 that would lie under the flip-chip bump 22 are removed via a commercial chrome etch or an HCl bath. As a result, the chrome layer 26 would consist essentially of the ring-shaped portion 30, with perhaps a slight extension under the area covered by the flip-chip bump 22. Any portions of the metal layer 20 not covered by the chrome layer 26 would, of course, be covered by the flip-chip bump 22. Thus, regardless of whether most or all of the underlying portion of the chrome layer 26 is removed, the metal layer 20 is covered by the ring-shaped portion 30 alone or in combination with the flip-chip bump 22.

The chrome layer 26 comprises a thin film having a thickness preferably in a range from about 200 Angstroms to about 2000 Angstroms, and more preferably from about 500 Angstroms to about 1500 Angstroms, and most preferably at about 1000 Angstroms. Due to its relative thinness, the chrome layer 26 amounts to a minute fraction of a wavelength at even millimeter wave frequencies. As a result, the RF performance of the MMIC 10 is not significantly affected by the portion 28 of the chrome layer 26 under the bump 22.

Because the chrome layer 26 is exposed to the ambient environment, a native oxide (not shown) develops on the surface of the chrome layer 26. Molten solder (e.g., 35/65 lead-tin or 50/50 lead-indium) commonly used for flip-chip attachment does not have the tendency to wet the native oxide on the surface of the chrome layer 26. This characteristic of the chrome layer 26 allows the ring-shaped portion 30 of the chrome layer 26 to replace the conventional dielectric solder dam.

In contrast to the output conductor 12, the collective source electrode 14 of the MMIC 10 has an electroplated thermal bump 32 disposed thereon. The structure of the solder dam for the thermal bump 32, however, is similar to the ring-shaped portion 30 of the chrome layer 26. More particularly, the thermal bump 32 is disposed over a circuit element having a chrome layer 34. According to one embodiment, the chrome layer 34 may have a portion 36 (FIG. 1B) under the thermal bump 32 and a portion 38 extending from the thermal bump 32 to act as a solder dam. The portions 36 and 38 of the chrome layer 34 may be disposed over (or alternatively upon) a plated gold bridge 40 (FIG. 1B) that couples respective source regions (not shown) of a multicell transistor. The source regions may be developed in the substrate 18 beneath respective ohmic metal portions 42 (FIG. 1B).

Alternatively, the chrome layer 34 may constitute only a ring-shaped solder dam that extends from the thermal bump 32 similar to the portion 38. As mentioned above, this ring-shaped solder dam may extend beneath the thermal bump 32 to a certain extent, as desired.

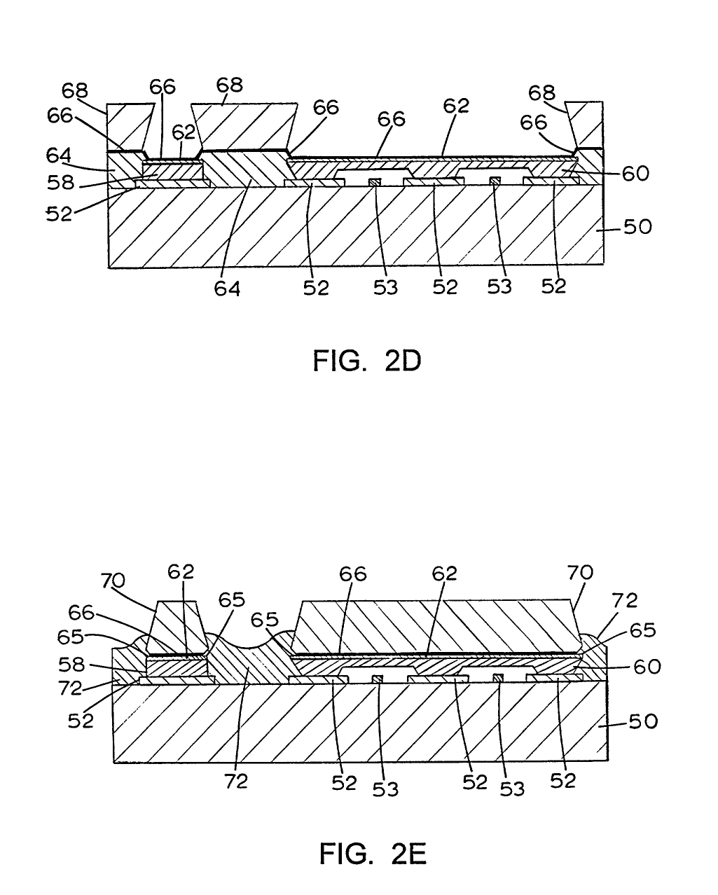

A process for fabricating a flip-chip semiconductor structure incorporating the chrome layer 26 as a solder dam and a dielectric adhesion agent will now be described in connection with FIGS. 2A-2E. A semiconductor substrate 50, which may comprise silicon, gallium arsenide, or any other suitable non-compound or compound semiconductor, has an ohmic metal layer 52 deposited thereon in accordance with conventional evaporation, sputtering, or other standard metal deposition techniques. The ohmic metal layer 52 is patterned via a prior photolithographic step and may comprise doped polysilicon or any one of the following metals, either alone or in combination: gold, germanium, and nickel (which may be in combination with a gold overlay). The thickness of the ohmic metal layer 52 is preferably in a range from about 500 Angstroms to about 2000 Angstroms, and more preferably from about 500 Angstroms to about 1000 Angstroms, and most preferably with about 750 Angstroms of gold/germanium, about 150 Angstroms of nickel, and about 1.5 microns of gold overlay.

At about this same time, multiple gate electrodes 53 are formed on the substrate 50 to establish multicell field-effect transistors. The structure, materials, and design of the gate electrodes are well known to those skilled in the art.

After the deposition of the ohmic metal portions 52 and the gate electrodes 53, a layer of photoresist is deposited and patterned via photolithography to form a bridge post resist layer 54. A bridge plating membrane 55 is then deposited, via evaporation, sputtering, or the like, on the bridge post resist layer 54 and the exposed portions of the ohmic metal portions 52. The bridge plating membrane 55 may comprise titanium and/or gold to facilitate an upcoming electroplating step, and may have a thickness of about 2000 Angstroms. The bridge post resist layer 54 protects the semiconductor structure (including, for instance, the gate electrodes 53) from this upcoming electroplating step.

Referring now to FIG. 2B, a layer of photoresist 56 is then spun onto the bridge plating membrane 55 and patterned via photolithography as shown. Turning to FIG. 2C, the patterned photoresist layer 56 defines a plated gold transmission line 58 and a plated gold bridge 60. The transmission line 58 and the bridge 60 are formed by a standard electroplating procedure to have a thickness preferably in a range from about one micron to about four microns, and more preferably in a range from about two microns to about four microns, and most preferably at about three microns. It should be noted that, unlike the transmission line 20 of FIG. 1B, the transmission line 58 is shown as coupled to a portion of the ohmic layer 52 (where, for instance, the transmission line 58 may be connected to a highly doped region of the substrate 50). This structure may, for example, correspond with the location where the collective source electrode for a multicell transistor is coupled to ground. Furthermore, the structure also provides a solid anchor for the bump to be formed thereon, as will be further explained below.

In accordance with one embodiment of the present invention, a thin film 62 of chrome is then electroplated onto the transmission line 58 and the gold bridge 60. While a hexavalent chrome plating bath may be utilized to deposit the chrome film 62, a trivalent chrome plating process is preferred. The high oxidation potential of hexavalent chromates may attack the masking photoresist during plating. With that exception, both types of plating baths are compatible with current flip-chip MMIC fabrication procedures. It should be noted that, unlike various prior solder dam fabrication techniques, no additional photolithographic step is required to develop the thin chrome film that will function as both a solder dam and dielectric adhesion agent.

As set forth above in greater detail, the chrome film 62 may have a thickness from about 200 Angstroms to about 2000 Angstroms. In accordance with the present invention, a native oxide layer (not shown) is allowed to form on the chrome film 62. The capability of this native oxide layer to share bonds with a dielectric material provides good adhesion characteristics for a chrome-passivation layer interface.

After the bridge post resist layer 54, the bridge plating membrane 55, and the photoresist layer 56 are removed via techniques known to those skilled in the art, a first bump photoresist layer 64 is spun onto the semiconductor structure and patterned via photolithography as shown in FIG. 2D. It should be noted that the first bump photoresist layer 64 (as patterned) covers a portion of the chrome film 62. In this manner, the flip-chip bumps to be formed later leave a small ring 65 (FIG. 2E) of the chrome film 62 exposed to act as the solder dam and adhesion agent. In accordance with one embodiment of the present invention, any exposed chrome is chemically removed at this point by a commercial chrome etch or an hydrochloric acid bath. With this chemical etch, the chrome layer 62 essentially assumes the shape of the ring-shaped portion 30 of FIGS. 1A and 1B.

A bump plating membrane 66 of titanium and/or gold is then deposited (via evaporation, sputtering, or another suitable deposition process) across the semiconductor structure, such that it covers both the first bump photoresist layer 64 and the chrome film 62 (in the event that it has not been etched away). The bump plating membrane 66 preferably has a thickness in a range from about 500 Angstroms to about 3000 Angstroms, and more preferably from about 1000 Angstroms to about 3000 Angstroms, and most preferably with about 2000 Angstroms of gold and about 200 Angstroms of titanium. The bump plating membrane 66 not only facilitates the silver electroplating step that forms the flip-chip bumps, but it also separates the first bump photoresist layer 64 from a second bump photoresist layer 68 that is deposited and patterned to form the profile shown in FIG. 2C. Alternative metals and/or materials for the bump plating membrane 66 include titanium, tungsten, and/or gold. The chrome film 62 has, however, exhibited excellent adhesion characteristics with the above-described evaporated gold/titanium bump plating membrane 66.

Referring now to FIG. 2E, an electroplating step forms silver bumps 70 according to the profile defined by the first and second bump photoresist layers 64 and 68. The silver bumps 70 may constitute either electrical or thermal flip-chip bumps. For example, the silver bump 70 formed over the gold bridge 60 is typically a thermal flip-chip bump, while the silver bump 70 formed over the transmission line 58 may be an electrical flip-chip bump. The silver electroplating procedure is well known to those skilled in the art and will not be further explained. Silver bumps are preferred, inasmuch as they exhibit superior thermal and electrical conductivity, but alternate metals suitable for the flip-chip bumps include gold and copper, either alone or in combination.

Silver migration is, in large part, inhibited by the solder used to couple the MMIC device to the assembly substrate. Migration may still occur if, for example, the solder does not entirely or adequately cover the silver bump. In that event, the titanium in the bump plating membrane 66 and the solder dam formed by the chrome film 62 further inhibits the silver from migrating to the gold metallization layer.

The thickness of the silver bumps 70 is preferably in a range from about 25 microns to about 105 microns, and more preferably from about 75 microns to about 105 microns, and is most preferably about 90 microns. It should be noted that the elements depicted in FIGS. 1 and 2A-2E are not necessarily shown to scale.

After formation of the silver bumps 70, solder is applied thereto for coupling the assembly substrate to the MMIC circuit disposed on the substrate 50. As is known to those skilled in the art, the solder is applied with a resin- or water-based flux. Both the solder and the flux may be selected from any of those typically used by those skilled in the art. In accordance with the present invention, the molten solder does not have the tendency to wet the native oxide of the exposed chrome film, thereby inhibiting its flow.

However, in accordance with an alternative embodiment of the present invention, a conventional dielectric passivation layer 72 may be deposited on the semiconductor structure prior to the application of solder. The passivation layer 72 may comprise silicon oxy-nitride or silicon dioxide, either alone or in combination, or any other dielectric known to those skilled in the art to be suitable for such deposition (e.g., plasma deposition techniques). The passivation layer 72 has a thickness typically in a range from about 0.5 microns to about 2.0 microns. While such dielectric materials exhibit poor bonding strengths when deposited directly on a gold surface, the chrome oxide on the surface of the rings 65 of the chrome film 62 provides an effective adhesion agent therefor. Without the adhesive characteristics of the chrome oxide, the MMIC device may become unpassivated during extreme thermal cycles and/or shocks. In this manner, the chrome film provides the flexibility to utilize both passivated and unpassivated circuit elements in a flip-chip environment.

It shall be noted that, as used herein, terms implying direction or orientation (e.g., “on” and “over”) should not be read to require any particular final orientation of the microwave device. For instance, if the MMIC 10 is eventually flipped for attachment to an assembly substrate, the chrome layer 26 may still be considered to be “under” the bump 22. Likewise, the bump 22 may still be understood to be “over” the chrome layer 26. Furthermore, the phrases “disposed over,” “deposited over,” and the like shall not be read to be limited to the context when two entities are in direct contact. For example, two layers that may be separated by a membrane or film may be referred to as “disposed over” one another.

Numerous other modifications and alternative embodiments of the invention will be apparent to those skilled in the art in view of the foregoing description. Accordingly, this description is to be construed as illustrative only. The details of the device and method may be varied substantially without departing from the spirit of the invention, and the exclusive use of all modifications which are within the scope of the appending claims is reserved.

What is claim is:

1. A microwave device, comprising:
a circuit element;
a layer comprising chromium disposed over the circuit element; and
a bump disposed over the circuit element.

2. The microwave device of claim 1, wherein the layer comprising chromium comprises a ring extending from the bump.

3. The microwave device of claim 2, wherein a bump plating membrane couples the bump to a metallic surface of the circuit element.

4. The microwave device of claim 2, wherein:
the layer comprising chromium further comprises a portion over which the bump is disposed; and
the ring comprises a solder dam.

5. The microwave device of claim 2, wherein the ring has a surface comprising chromium oxide.

6. The microwave device of claim 5, further comprising a dielectric passivation layer disposed on the surface of the ring.

7. The microwave device of claim 1, wherein the layer comprises electrolytically plated chromium.

8. The microwave device of claim 1, wherein the layer has a thickness in a range from about 200 Angstroms to about 2000 Angstroms.

9. The microwave device of claim 1, wherein the circuit element has a surface comprising gold.

10. The microwave device of claim 1, wherein the bump comprises a flip-chip bump.

11. The microwave device of claim 1, wherein the bump comprises a thermal flip-chip bump.

12. A method of forming a flip-chip bump on a circuit element of microwave device, comprising the steps of:
(a) depositing a layer comprising chromium over the circuit element;
(b) providing a bump photoresist profile; and
(c) depositing a metal layer over the circuit element to form the flip-chip bump according to the bump photoresist profile.

13. The method of claim 12, further comprising the step of removing, prior to step (b), a plating membrane and a photoresist layer both of which are utilized to form the circuit element.

14. The method of claim 13, further comprising the step of removing a portion of the layer comprising chromium to leave a ring-shaped portion extending from the flip-chip bump.

15. The method of claim 12, wherein step (b) comprises the step of depositing a bump plating membrane.

16. The method of claim 15, wherein the bump plating membrane is deposited on the layer comprising chromium.

17. The method of claim 12, wherein the circuit element has a surface comprising gold.

18. The method of claim 17, wherein step (a) comprises the step of electroplating chromium on the surface comprising gold.

19. The method of claim 12, wherein:
the bump photoresist profile covers a portion of the layer comprising chromium; and
the method further comprises the steps of:
removing the bump photoresist profile; and
allowing a native oxide to grow on the portion of the layer comprising chromium to form a solder dam.

20. The method of claim 19, wherein the portion of the layer comprising chromium comprises a ring extending from the flip-chip bump.

21. The method of claim 19, further comprising the step of depositing a dielectric material on the portion of the layer comprising chromium to form a passivation layer.
